(19) United States
(12) Patent Application Publication
(10) Pub. No.: US 2025/0172861 A1
(43) Pub. Date: May 29, 2025

(54) HEAT DISSIPATION MODULE AND PROJECTION DEVICE

(71) Applicant: Coretronic Corporation, Hsin-Chu (TW)

(72) Inventors: Pei-Rong Wu, Hsin-Chu (TW); Shi-Wen Lin, Hsin-Chu (TW)

(73) Assignee: Coretronic Corporation, Hsin-Chu (TW)

(21) Appl. No.: 18/943,921

(22) Filed: Nov. 12, 2024

(30) Foreign Application Priority Data
Nov. 28, 2023 (CN) 202311598225.7

(51) Int. Cl. G03B 21/16; G03B 21/14; H05K 7/20

(52) U.S. Cl. CPC G03B 21/16; G03B 21/145; H05K 7/20145; H05K 7/20172; H05K 7/20409

(57) ABSTRACT

A heat dissipation module configured to dissipate heat from a rotating element rotated with a first axis as a rotation axis is provided. The heat dissipation module includes at least one first fan and a heat dissipation component. The at least one first fan includes a first fan outlet. A first airflow generated by the at least one first fan flows from the first fan outlet to the rotating element. The heat dissipation component includes an inlet duct, a plurality of inner ducts and at least one outlet duct. The plurality of inner ducts are communicated to the inlet duct and the at least one outlet duct. The inlet duct of the heat dissipation component is disposed corresponding to a rotation tangential direction of the rotating element, and the rotation tangential direction is perpendicular to the first axis. In addition, a projection device is also mentioned.

### CROSS-REFERENCE TO RELATED APPLICATION

This application claims the priority benefit of China application serial no. 202311598225.7 filed on Nov. 28, 2023. The entirety of the above-mentioned patent application is hereby incorporated by reference herein and made a part of this specification.

### BACKGROUND

### Technical Field

The disclosure relates to a heat dissipation module and a projection device including this heat dissipation module.

### Description of Related Art

The heat dissipation way the rotating element (such as fluorescent color wheels, color

filter wheels or light diffusion wheels, etc.) of the modern projection devices located on the light path is, for example, to use fans to provide cooling airflow to cool down. Since the rotating element shares the space inside projection devices with other elements (such as an optical machine), the airflow with high thermal energy after heat exchange with the rotating element affects other elements, and the airflow with high thermal energy is not easy to be discharged. In addition, the rotation direction of the rotating element also affects the heat dissipation effect of the rotating element.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

A heat dissipation module and a projection device, which have good heat dissipation performance, are provided in the disclosure.

The other objectives and advantages of the disclosure may be further understood from the descriptive features disclosed in the disclosure.

In order to achieve one of, or portions of, or all of the above objectives or other objectives, the liquid cooling module is configured to dissipate heat from a rotating element rotated with a first axis as a rotation axis. The heat dissipation module includes at least one first fan and a heat dissipation component. The at least one first fan is disposed to one side of the rotating element and includes a first fan outlet. The first fan outlet faces the rotating element, a first airflow generated by the at least one first fan flows from the first fan outlet to the rotating element. The heat dissipation component includes an inlet duct, a plurality of inner ducts and at least one outlet duct. The plurality of inner ducts are communicated to the inlet duct and the at least one outlet duct, the at least one outlet duct corresponds to the at least one first fan. The inlet duct of the heat dissipation component is disposed corresponding to a rotation tangential direction of the rotating element, and the rotation tangential direction is perpendicular to the first axis. In addition, a projection device is also mentioned.

In order to achieve one of, or portions of, or all of the above objectives or other objectives, the projection device includes an illumination system, a light valve and a lens module. The illumination system is configured to provide an illumination beam, the illumination system includes a light source module, a heat dissipation module and a rotating element. The light source module is configured to provide a light beam, the rotating element is disposed on a transmission path of at least part of the light beam. The rotating element rotates around a first axis as a rotation axis, and the illumination beam includes at least part of the light beam. The heat dissipation module is configured to dissipate heat to the rotating element, and the heat dissipation module includes at least one first fan and a heat dissipation component. The at least one first fan is disposed to one side of the rotating element and includes a first fan outlet. The first fan outlet faces the rotating element, and a first airflow generated by the at least one first fan flows from the first fan outlet to the rotating element. The heat dissipation component includes an inlet duct, a plurality of inner ducts and at least one outlet duct. The plurality of inner ducts are communicated to the inlet duct and the at least one outlet duct, the at least one outlet duct corresponds to the at least one first fan, wherein the inlet duct of the heat dissipation component is disposed corresponding to a rotation tangential direction of the rotating element, and the rotation tangential direction is perpendicular to the first axis. The light valve is disposed on a transmission path of the illumination beam to convert the illumination beam into an image beam. The lens module is disposed on a transmission path of the image beam to project the image beam.

Based on the above, the heat dissipation module of the disclosure dissipates heat from the rotating element through the heat dissipation component and the first fan. The first fan generates a first airflow to cool the rotating element. The inlet duct of the heat dissipation component corresponds to the rotation tangential direction of the rotating element, whereby the rotating element guides the first airflow into the heat dissipation component to cool the first airflow, to improve the heat dissipation efficiency of the heat dissipation module and the projection device.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a block diagram of a projection device according to an embodiment of the disclosure.

FIG. 2 is a schematic diagram of the heat dissipation module of FIG. 1.

FIG. 3 is a schematic diagram of the heat dissipation component of FIG. 2.

FIG. 4 is a top schematic view of the heat dissipation module of FIG. 2.

FIG. 5 is a side schematic view of the heat dissipation module of FIG. 2.

FIG. 6 is a schematic diagram of the housing of FIG. 1.

FIG. 7 is a schematic diagram of a rotating element and a heat dissipation component according to another embodiment of the disclosure.

FIG. 8 is a schematic diagram of a heat dissipation module according to another embodiment of the disclosure.

FIG. 9 is a schematic diagram of the heat dissipation component of FIG. 8.

FIG. 10 is a top schematic view of the heat dissipation module of FIG. 8.

FIG. 11 is a side schematic view of the heat dissipation module of FIG. 8.

FIG. 12 is a schematic diagram of the housing of FIG. 8.

FIG. 13 is a schematic diagram of a heat dissipation module according to another embodiment of the disclosure.

FIG. 14 is a schematic diagram of a heat dissipation module according to another embodiment of the disclosure.

FIG. 15 is a side schematic view of the heat dissipation module of FIG. 14.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention may be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

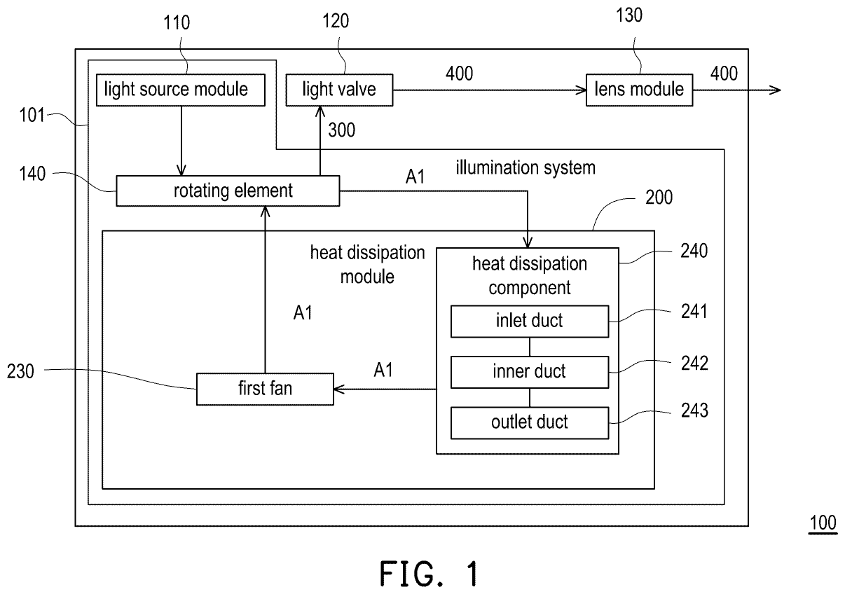

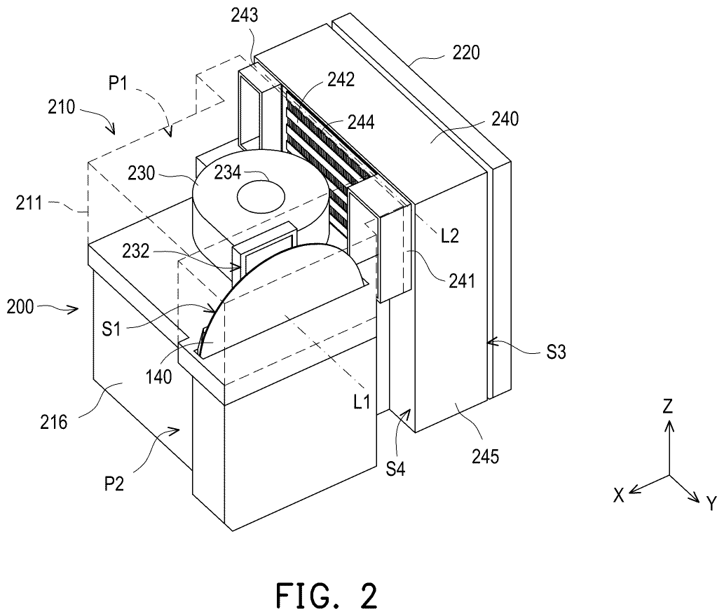

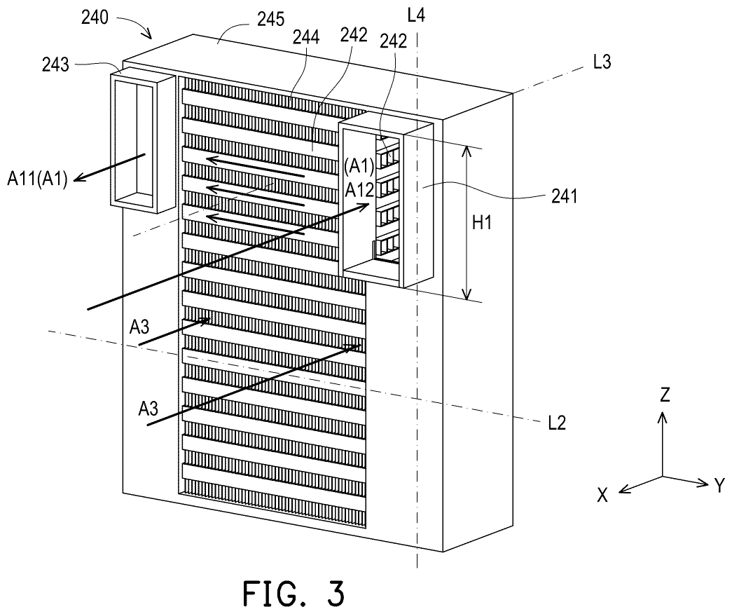

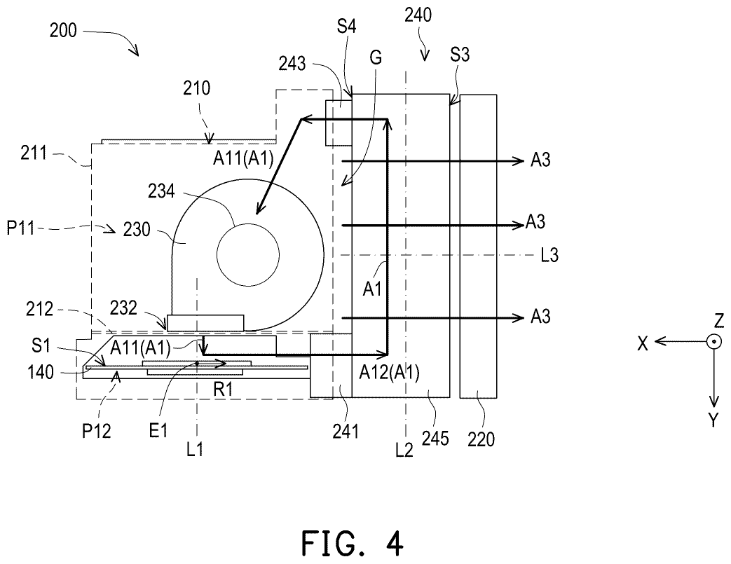

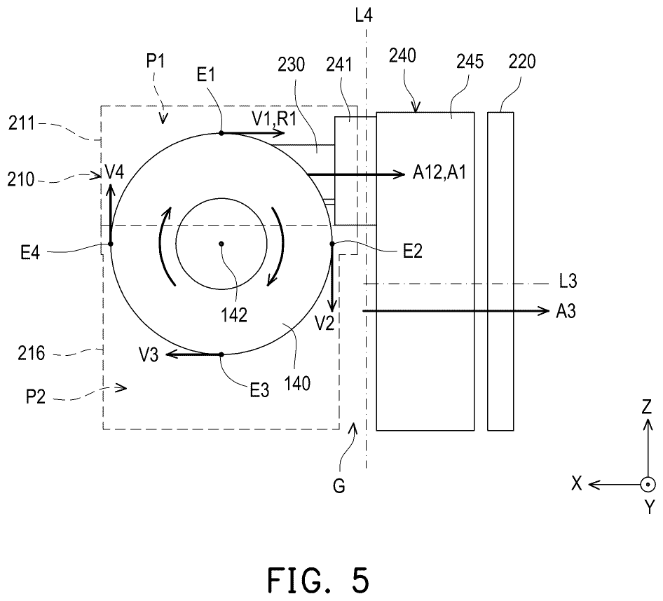

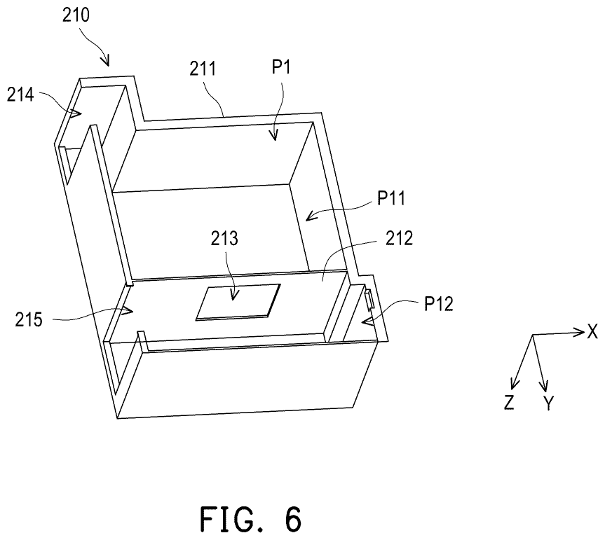

FIG. 1 is a block diagram of a projection device according to an embodiment of the disclosure. FIG. 2 is a schematic diagram of the heat dissipation module of FIG. 1. FIG. 3 is a schematic diagram of the heat dissipation component of FIG. 2. FIG. 4 is a top schematic view of the heat dissipation module of FIG. 2. FIG. 5 is a side schematic view of the heat dissipation module of FIG. 2. FIG. 6 is a schematic diagram of the housing of FIG. 1. Cartesian coordinates X-Y-Z are provided here to facilitate component description. Referring to FIG. 1 to FIG. 6, a projection device 100 includes an illumination system 101, a light valve 120 and a lens module 130. The illumination system 101 is configured to provide an illumination beam 300, the illumination system 101 includes a light source module 110, a heat dissipation module 200 and a rotating element 140. The light source module 110 is configured to provide a light beam. The rotating element 140 is disposed on a transmission path of at least part of the light beam, the illumination beam 300 includes at least part of the light beam. The light valve 120 is disposed on a transmission path of the illumination beam 300 from the light source module 110 to convert the illumination beam 300 into an image beam 400. The lens module 130 is disposed on a transmission path of the image beam 400 to project the image beam 400 out of the projection device 100. The heat dissipation module 200 is configured to dissipate heat of the rotating element 140. The rotating element 140 of this embodiment, for example, is a phosphor wheel, a filter wheel, or a diffuser wheel, but not limited thereto. The rotating element 140 rotates around a first axis L1, the first axis L1 is considered as a rotation axis, and the first axis L1 is parallel to the Y-axis.

The light source module 110 includes, for example, a light-emitting diode (LED) element or a laser diode (LD) element, and is a single light emitting element or an array of light emitting elements. The light valve 120 includes, for example, one of a reflective light modulator such as a liquid crystal on silicon panel (LCoS panel) and a digital micro-mirror device (DMD). In some embodiments, the light valve 120 may also include one of the transmissive optical modulator, such as a transparent liquid crystal panel, an electro-optical modulator, a magneto-optical modulator, or an acousto-optic modulator (AOM), etc. This disclosure does not limit the form and type of the light valve 120. The light valve 120 converts the illumination beam 300 of different colors to the image beam 400 according to different timings and transmits the image beam 400 to the lens module 130 after the illumination beam 300 of different colors irradiates the light valve 120. Therefore, the image beam 400 converted by the light valve 120 forms the image picture that is projected out of the projection device 100, so as to become a color picture. The detailed process and implementation for the light valve 120 to convert the illumination beam 300 into the image beam 400 may be obtained from general knowledge in the technical field with sufficient teaching, suggestion and implementation description, and therefore will not be repeated. In this embodiment, the number of light valve 120 is one, such as a projection device 100 using a single digital micro-mirror element, but in other embodiments there may be more than one light valve 120, and the disclosure is not limited to this.

The lens module 130 includes, for example, a combination of one or more optical lenses with diopter, such as various combinations of non-planar lenses such as biconcave lenses, biconvex lenses, meniscus lenses, convex-concave lenses, plano-convex lenses, and plano-concave lenses. In one embodiment, the lens module 130 may further include a planar, concave, or convex optical lens to project the image beam 400 to a projection target (for example, a wall or a projection screen). This disclosure does not limit the form and type of the lens module 130.

As shown in FIG. 1 to FIG. 4, the heat dissipation module 200 includes at least one first fan 230 and a heat dissipation component 240. The number of the first fan 230 of this embodiment is one, but is not limited thereto. The first fan 230 is disposed on one side S1 of the rotating element 140 and includes a first fan outlet 232. The first fan 230 is configured to generate a first airflow A1. The first airflow A1 with lower thermal energy flows from the first fan outlet 232 to the rotating element 140 to perform heat exchange with the rotating element 140. The heat dissipation component 240 receives the first airflow A1 with higher thermal energy after heat exchange with the rotating element 140. The first airflow A1 performs heat exchange within the heat dissipation component 240 and/or the external environment to cool the first airflow A1. The cooled first airflow A1 returns to the first fan 230. The first airflow A1 completes one cooling cycle.

The heat dissipation module 200 continuously cools the rotating element 140 through the circulation of the first airflow A1. The heat dissipation module 200 as a whole dissipates heat for the rotating element 140, and the hot airflow after heat exchange with the first airflow A1 is directly discharged from the heat dissipation module 200 and the projection device 100 to improve the heat dissipation efficiency of the heat dissipation module 200 and the projection device 100. As a benefit of the above configuration, the heat dissipation module 200 may maintain a compact configuration, so as to reduce the volume of the heat dissipation module 200.

In one embodiment, the heat dissipation component 240 includes an inlet duct 241, a plurality of inner ducts 242 and at least one outlet duct 243. The inner ducts 242 are communicated to the inlet duct 241 and at least one outlet duct 243. At least one outlet duct 243 corresponds to at least one first fan 230. The number of outlet ducts 243 of this embodiment is one, but is not limited thereto. As the embodiment shown in FIG. 3 and FIG. 4, the heat dissipation component 240 further includes a body 245 and a plurality of fins 244. The inner ducts 242 are extended along a second axis L2. The second axis L2 is parallel to the first axis L1 (ie, parallel to the Y-axis). The inlet duct 241 and the outlet duct 243 are connected to the body 245, and the inner ducts 242 and the fins 244 are disposed in the body 245. In other embodiments, the inner ducts 242 are extended along the second axis, and the second axis L2 may not be parallel to the first axis L1. For example, there is an included angle between the second axis and the first axis L1 that is greater than 0 and less than 90, this disclosure does not limit thereto.

The inner duct 242 of this embodiment has a rectangular cross-sectional shape perpendicular to the second axis L2, and the inner duct 242 is specifically a flat tube, so that the inner ducts 242 are arranged compactly to increase a space usage of the heat dissipation component 240. As shown in FIG. 3, the inner ducts 242 are extended along the second axis L2 and are arranged along a third axis L3. One end opening of each of the inner ducts 242 is communicated to the inlet duct 241, and the other end opening of each of the inner ducts 242 is communicated to the outlet duct 243. The fins 244 of the heat dissipation component 240 are connected between any two adjacent inner ducts 242 and are located between the inner ducts 242 and the body 245. The first airflow A1 flows in the inner ducts 242 and exchanges heat with the external environment through the inner ducts 242 and the fins 244. The fins 244 are configured to increase a heat dissipation area of the inner ducts 242, so as to increase the heat dissipation efficiency of the heat dissipation component 240 for the first airflow A1.

As shown in FIG. 3 and FIG. 4, at least part of the first airflow A1 passes through the rotating element 140 and is guided into the body 245 of the heat dissipation component 240 through the inlet duct 241, and flows through the plurality of inner ducts 242 to the outlet duct 243. The first airflow A1 leaves the heat dissipation component 240 from the corresponding outlet duct 243. The outlet duct 243 is disposed corresponding to a first fan inlet 234 of the first fan 230. The first fan 230 is located between the inlet duct 241 and the outlet duct 243, and is disposed on a flow path of at least part of the first airflow A1 between the inlet duct 241 and the outlet duct 243.

Referring to FIG. 3 and FIG. 4 continuously, the heat dissipation module 200 further includes a housing 210. The heat dissipation module 200 of this embodiment optionally includes an auxiliary fan 220. The auxiliary fan 220 and the housing 210 are respectively disposed on two opposite sides S3 and S4 of heat dissipation component 240. The auxiliary fan 220 is configured to generate an auxiliary airflow A3 to dissipate heat from the inner ducts 242 and the fins 244 of the heat dissipation component 240, so as to further cool the first airflow A1. The auxiliary airflow A3 is driven by the auxiliary fan 220 to pass through the voids between the adjacent fins 244 along the third axis L3, and exchanges heat with the first airflow A1 flowing in the inner ducts 242. After heat exchange, the auxiliary airflow A3 with high thermal energy leaves the projection device 100 (heat dissipation module 200) in a direction away from the rotating element 140. The auxiliary airflow A3 moves through the voids between the fins 244 along the third axis L3. The third axis L3 is parallel to the X-axis, and the second axis L2 is perpendicular to the third axis L3. The auxiliary fan 220 is, for example, a model 9225 cooling fan, but is not limited thereto.

As shown in FIG. 2 and FIG. 4, the housing 210 of the heat dissipation module 200 includes a first space P1 and a second space P2. The rotating element 140 rotates around the first axis L1 as the rotation axis and is located in the first space P1 and the second space P2 of the housing 210. The first fan 230 is disposed in the first space P1 of the housing 210, and the first fan outlet 232 of the first fan 230 faces the rotating element 140. The heat dissipation component 240 is disposed outside the housing 210. The inlet duct 241 and the outlet duct 243 of the heat dissipation component 240 are connected between the body 245 of the heat dissipation component 240 and the housing 210, and the heat dissipation component 240 is communicate with the first space P1 of the housing 210 through the inlet duct 241 and the outlet duct 243. There is a gap G between the body 245 of the heat dissipation component 240 and the housing 210. The side of the body 245 facing the gap G is regarded as the inlet of the auxiliary airflow A3. The auxiliary airflow A3 driven by the auxiliary fan 220 flows into the gap G between the body 245 and the housing 210, and flows from the body 245 to the auxiliary fan 220.

The housing 210 specifically includes a first housing 211 and a second housing 216. In this embodiment, the first housing 211 and the second housing 216, for example, are disposed along the Z-axis, and the first housing 211 and the second housing 216 form the first space P1 and the second space P2 after being assembled. The first housing 211 defines the first space P1, and the second housing 216 defines the second space P2. The first fan 230 is disposed in the first housing 211, and the rotating element 140 is located in the first housing 211 and the second housing 216. The housing 210 and the inlet duct 241, inner ducts 242 and outlet duct 243 of the heat dissipation component 240 form a sealing space to prevent the first airflow A1 from escaping to the outside to reduce the heat dissipation efficiency of the heat dissipation module 200.

As shown in FIG. 2 to FIG. 6, the first housing 211 of the housing 210 includes at least one partition plate 212, at least one first opening 214 and a second opening 215. The first space P1 is divided into at least one first subspace P11 and a second subspace P12 by the partition plate 212. The number of the first openings 214 of this embodiment corresponding to the number of outlet ducts 243 and is one, and the number of partition plates 212 is one to separate one first subspace P11, but is not limited thereto. The first opening 214 of this embodiment corresponds to the first subspace P11, and the second opening 215 corresponds to the second subspace P12. The partition plate 212 includes a fan opening 213. The first fan 230 is located in the first subspace P11, and part of the rotating element 140 is located in the second subspace P12. The fan opening 213 corresponds to the first fan outlet 232 of the first fan 230. The outlet duct 243 of the heat dissipation component 240 is connected to the first opening 214 of the first housing 211, and the inlet duct 241 of the heat dissipation component 240 is connected to the second opening 215 of the first housing 211. Through the above configuration, the heat dissipation component 240 communicates with the first space P1 of the first housing 211.

As shown in FIG. 5, the first space P1 defined by the first housing 211 of the housing 210 of this embodiment is located above the second space P2 defined by the second housing 216 along the Z-axis direction, but not limited thereto. The inlet duct 241 of the heat dissipation component 240 corresponds to an outer circumference of the rotating element 140. The relative positions of the first space P1 and the second space P2 of the housing 210 and the installation position of the inlet duct 241 are related to the rotation tangential direction R1 of the rotating element 140, which is further described below.

Referring to FIG. 5 together with FIG. 2 to FIG. 4 continuously, when the rotating element 140 rotates around the first axis L1 (parallel to the Y-axis) as the rotation axis, any edge positions (taking four edge positions E1, E2, E3, and E4 in FIG. 5 as examples) on the outer circumference of the rotating element 140 respectively have corresponding tangential directions V1, V2, V3, and V4 located on the rotate tangent of the rotation of the rotating element 140 generated by to the rotation of the rotating element 140. In this embodiment, the inlet duct 241 of the heat dissipation component 240 is disposed corresponding to the rotation tangential direction R1 of the rotating element 140, and the rotation tangential direction R1 is perpendicular to the first axis L1. The first fan outlet 232 is disposed to correspond to the edge position adjacent to the outer circumference of the rotating element 140, such as the edge position E1 shown in FIG. 4, and the first airflow A1 from the first fan outlet 232 flows toward the heat dissipation component 240 along the rotation tangential direction R1.

The four edge positions E1, E2, E3, and E4 of the example take turns passing through the first fan outlet 232 during the rotation of the rotating element 140 (in FIG. 5, since the rotating element 140 is rotated clockwise, the edge positions pass through the first fan outlet 232 in an order of E4, E3, E2, E1), this embodiment uses the edge position E1 as shown in FIG. 5 as an example, and the following continues the explanation using the diagram presented in FIG. 5. The inlet duct 241 of the heat dissipation component 240 is disposed corresponding to the rotation tangential direction R1 to ensure that most of the first airflow A1 is guided by the rotating element 140 along the rotation tangential direction R1 and flows into the inlet duct 241, and flows into heat dissipation component 240 through the inlet duct 241. The rotation tangential direction R1 is toward the inlet duct 241 of the heat dissipation component 240. This embodiment is explained based on the rotation tangential direction R1 parallel to the third axis L3 (X-axis).

Referring to FIG. 5 continuously, when the rotating element 140 of this embodiment rotates clockwise with the first axis L1 (parallel to the Y-axis) as the rotation axis, for example, the tangential direction V1 of the edge position E1 shown in FIG. 5 is parallel to the third axis L3 (parallel to the X-axis) and faces the heat dissipation component 240, the tangential direction V1 is the rotation tangential direction R1. The space where the edge position E1 as shown in FIG. 5 is located in the first space P1 of the housing 210. The inlet duct 241 corresponds to the position of the rotation tangential direction R1 shown in FIG. 5. An orthographic projection of the edge position E1 shown in FIG. 5 to the heat dissipation component 240 overlaps the inlet duct 241. In one embodiment, the length H1 of the inlet duct 241 along an extension axis L4 (as shown in FIG. 3) is designed to be equal to a radius of the rotating element 140, so that most of the first airflow A1 is guided by the rotating element 140 along the rotation tangential direction R1 and flows to the inlet duct 241 to obtain a better airflow guidance effect, but is not limited thereto. The extension axis L4 is parallel to the Z-axis and perpendicular to the first axis L1, and the extension axis L4 is perpendicular to the normal direction of an air inlet surface of the inlet duct 241.

FIG. 4 schematically illustrates a flow direction of the first airflow A1 with arrows to explain in detail a cooling cycle process of the first airflow A1. As shown in FIG. 4, since the rotating element 140 is located on the at least part of the transmission path of the light beam (referring to FIG. 1), a large amount of thermal energy is accumulated when the rotating element 140 is continuously irradiated by the light beam and is regarded as a heat source. The first airflow A1 with smaller thermal energy generated from the first fan outlet 232 of the first fan 230 is defined as a first cooling airflow A11. The first cooling airflow A11 (the first airflow A1 with smaller thermal energy) performs heat exchange with the rotating element 140 to cool the rotating element 140. The first airflow A1 after heat exchange has greater thermal energy and is defined as a first hot airflow A12. The first hot airflow A12 (the first airflow A1 with greater thermal energy) is guided by the rotating element 140 and enters the body 245 of the heat dissipation component 240 through the inlet duct 241, and flows to the inner ducts 242 (as shown in FIG. 3). FIG. 3 schematically illustrates the flow of the first hot airflow A12 in the three inner ducts 242 with three arrows, but is not limited thereto. Preferably, the first hot airflow A12 flows in all inner ducts 242.

As shown in FIG. 3 and FIG. 4, during the first hot airflow A12 (the first airflow A1) flows in the inner duct 242, when the first hot airflow A12 flows through the inner duct 242, first hot airflow A12 is dissipated heat by the fins 244, the auxiliary airflow A3 flows through the fins 244 for heat exchange. After heat exchange, the auxiliary airflow A3 with greater thermal energy flows in the direction away from the heat dissipation module 200. After heat exchange, the first airflow A1 with smaller thermal energy leaves the heat dissipation component 240 from the outlet duct 243 to form the first cooling airflow A11. At least part of the first cooling airflow A11 enters the first fan inlet 234 of the first fan 230. Then, the first cooling airflow A11 (the first airflow A1) is blown out from the first fan outlet 232. At this point, the heat dissipation module 200 completes one cooling cycle. The first airflow A1 continuously dissipates heat to the rotating element 140 through the heat dissipation cycle.

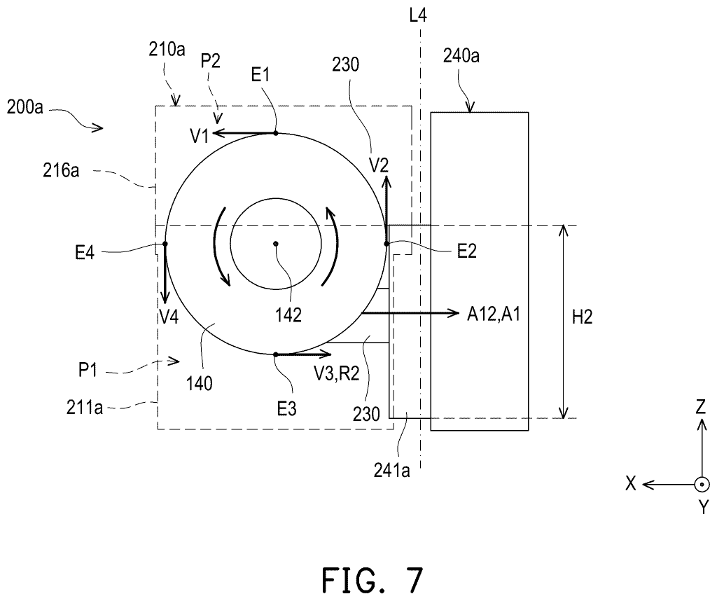

FIG. 7 is a schematic diagram of a rotating element and a heat dissipation component according to another embodiment of the disclosure. The heat dissipation module 200a of this embodiment is similar to the previous embodiment. The difference between the two is that the rotating element 140 of this embodiment rotates in the counterclockwise direction with the first axis L1 (parallel to the Y-axis) as the rotation axis. At this time, the first fan outlet (not shown) is disposed to correspond to the edge position adjacent to the outer circumference of the rotating element 140, such as the edge position E3 shown in FIG. 7. The first airflow A1 from the first fan outlet flows toward the inlet duct 241a of the heat dissipation component 240a along the rotation tangential direction R2. Taking the edge position E3 shown in FIG. 7 as an example, the tangential direction V3 of the edge position E3 is parallel to the X-axis and faces the heat dissipation component 240a. The first space P1 defined by the first housing 211a of the housing 210a corresponds to the edge position E3 in FIG. 7. The first space P1 is located below the second space P2 defined by the second housing 216a along the Z-axis direction (i.e. parallel to the extension axis L4). The inlet duct 241a of the heat dissipation component 240a corresponds to the outer circumference of the rotating element 140, such as the edge position E3 shown in FIG. 7.

The length H2 of the inlet duct 241a of this embodiment along the extension axis L4 is greater than the radius of the rotating element 140, and smaller than a diameter of the rotating element 140. The orthographic projection of the outer circumference of the rotating element 140 to the heat dissipation component 240a along the X-axis, such as the edge position E3 shown in FIG. 7, overlaps the inlet duct 241a. It can be seen that, the arrangement of the housing 210a and the arrangement of the inlet duct 241a of the heat dissipation component 240a are changed according to the rotation direction of the rotating element 140. The heat dissipation module 200a of this embodiment has the same effect as the previous embodiment, and is not repeated herein.

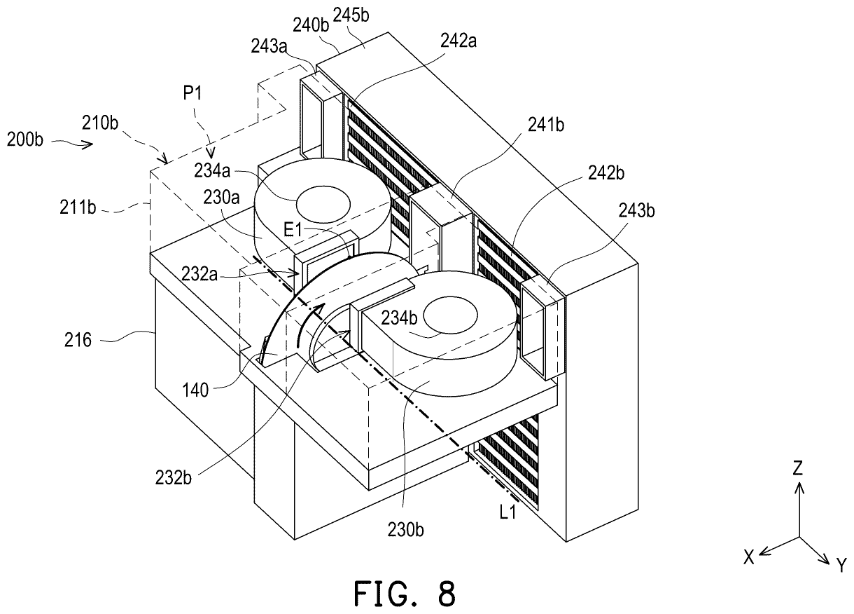

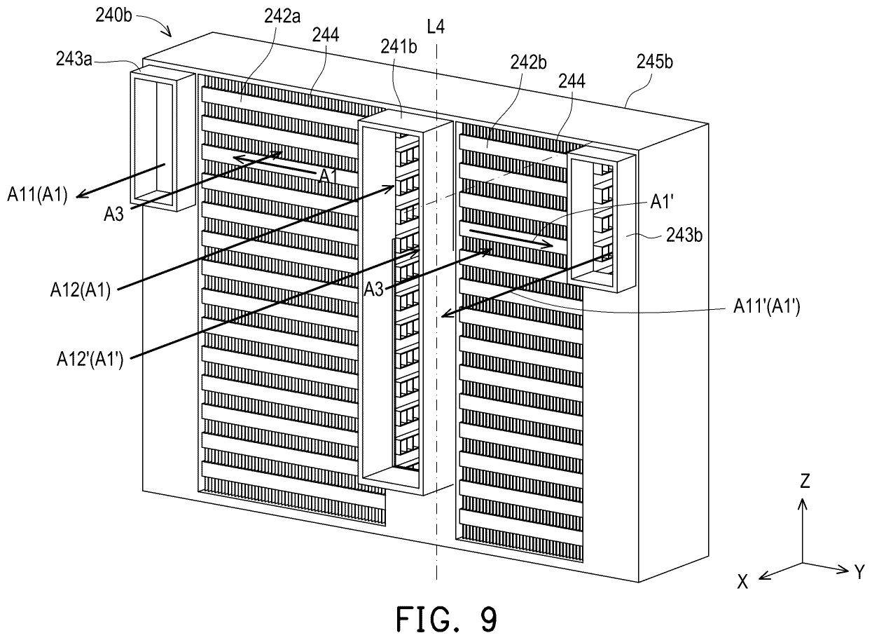

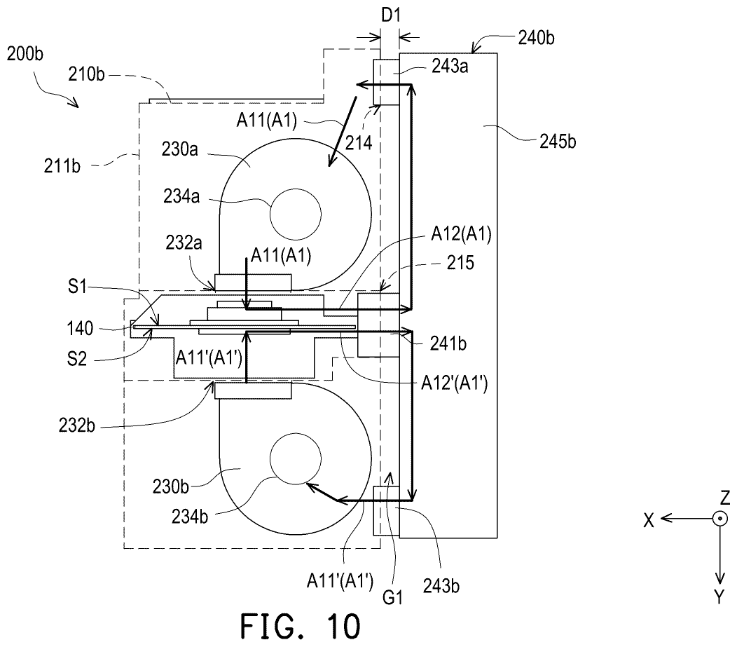

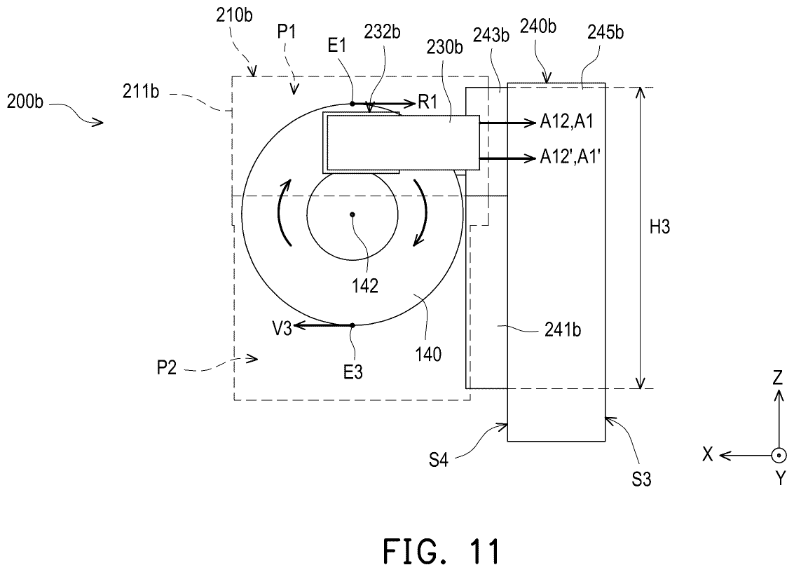

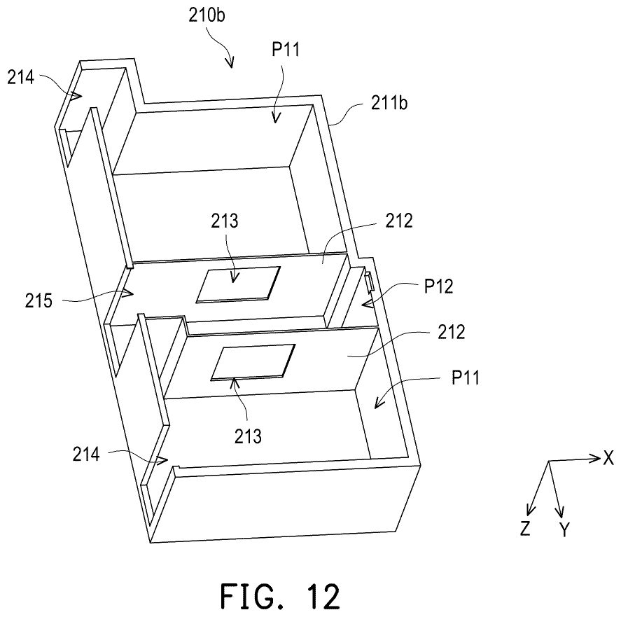

FIG. 8 is a schematic diagram of a heat dissipation module according to another embodiment of the disclosure. FIG. 9 is a schematic diagram of the heat dissipation component of FIG. 8. FIG. 10 is a top schematic view of the heat dissipation module of FIG. 8. FIG. 11 is a side schematic view of the heat dissipation module of FIG. 8. FIG. 12 is a schematic diagram of the housing of FIG. 8. Referring to FIG. 8 to FIG. 12 at the same time, in this embodiment, the number of first fans 230a and 230b of the heat dissipation module 200b is two. The two first fans 230a and 230b are disposed on two opposite sides S1 and S2 of the rotating element 140. The number of outlet ducts 243a and 243b of the heat dissipation component 240b is two, and the inlet duct 241b is located between the two outlet ducts 243a and 243b. Part of the inner ducts 242a are communicated to the outlet duct 243a and the inlet duct 241b, and the other part of the inner ducts 242a are communicated to the outlet duct 243b and the inlet duct 241b.

As shown in FIG. 10 to FIG. 12, the number of the first openings 214 of the first housing 211b of the housing 210b is two, the number of the partition plates 212 is two, and the two partition plates 212 separate the two first subspaces P11 and the second subspace P12. The second subspace P12 is located between the two first subspaces P11, and the second opening 215 is located between the two first openings 214. There is a distance D1 between the body 245b of the heat dissipation component 240b and the housing 210b, and a size of the gap G1 between the body 245b and the housing 210b depends on the distance D1. The length H3 of the inlet duct 241b of the heat dissipation component 240b on the Z-axis is greater than the diameter of the rotating element 140, and the orthographic projection of the center 142 of the rotating element 140 to the heat dissipation component 240b along the X-axis overlaps the inlet duct 241b. In an embodiment not shown, the length of the inlet duct 241b along the Z-axis may be equal to the diameter of the rotating element 140.

As shown in FIG. 9 and FIG. 10, the two first fan inlets 234a and 234b of the two first fans 230a and 230b are respectively disposed corresponding to the two outlet ducts 243a and 243b. The first fan outlet 232a of the first fan 230a and the first fan outlet 232b of the first fan 230b are aligned with each other. The two first fans 230a and 230b respectively generate two first airflows A1 and A1′ (the first cooling airflows A11 and A11′) to dissipate heat from the rotating element 140.

FIG. 9 and FIG. 10 schematically illustrate the flow directions of the two first airflows A1 and A1′ with arrows. The two first cooling airflows A11 and A11′ respectively perform heat exchange with the rotating element 140 to form corresponding the two first hot airflows A12 and A12′. The two first hot airflows A12 and A12′ are guided by the rotating element 140 and enter the heat dissipation component 240b from the inlet duct 241b. The first hot airflow A12 dissipates heat through the heat dissipation component 240b to form the first cooling airflow A11. The first cooling airflow A11 leaves the heat dissipation component 240b from the outlet duct 243a, and enters the first fan inlet 234a of the first fan 230a. The heat of the first hot airflow A12′ is dissipated through the heat dissipation component 240b to form the first cooling airflow A11′. The first cooling airflow A11′ leaves the heat dissipation component 240b from the outlet duct 243b, and enters the first fan inlet 234b of the first fan 230b. The heat dissipation module 200b of this embodiment has similar effects to the previous embodiment, and is not repeated herein.

In the known heat dissipation module, two fans are disposed at the two sides of the rotating element to cool the rotating element. When the rotation speed of the rotating element is 7200 rpm and the rotating element rotates clockwise, the temperature of the two airflows generated by the two fans are between 45 degrees Celsius and 50 degrees Celsius. The rotating element is cooled to approximately 302 degrees Celsius. When the rotating element rotates counterclockwise, the temperature of the two airflows generated by the two fans are between 45 degrees Celsius and 55 degrees Celsius. The rotating element is cooled to approximately 268 degrees Celsius.

When the heat dissipation module 200b of this embodiment dissipates heat from the rotating element 140 with the rotation speed of 7200 rpm, the temperature of the two first cooling airflows A11 and A11′ generated by the two first fans 230a and 230b are between 35 degrees Celsius and 42 degrees Celsius, and the rotating element 140 is cooled to 248 degrees Celsius through the heat dissipation module 200b. The orthographic projection of the edge positions E1 and E3 of the rotating element 140 to the heat dissipation component 240b shown in this embodiment are located in the inlet duct 241b, even if the rotating element 140 rotates counterclockwise (the rotating element 140 shown in FIG. 11 rotates clockwise), the rotating element 140 is still cooled to 249 degrees Celsius through the heat dissipation module 200b. The temperature of the two first cooling airflows A11 and A11′ generated by the two first fans 230a and 230b are between 34 degrees Celsius and 40 degrees Celsius.

It can be seen that compared with the known heat dissipation module, the heat dissipation module 200b of this embodiment is more effectively reducing the temperature of the first cooling airflow A11, A11′ generated by the first fans 230a, 230b, and is more effectively cooling the rotating element 140.

In addition, the heat dissipation module 200b of this embodiment may also include the auxiliary fan 220 of the previous embodiment shown in FIG. 4 (not shown in FIG. 8 to FIG. 12). The auxiliary fan 220 shown in FIG. 4 and the housing 210b of this embodiment are located on the two opposite sides S3 and S4 of the heat dissipation component 240b. When the auxiliary fan 220 is disposed, the rotation speed of the rotating element 140 is 14400 rpm, and the rotating element 140 rotates clockwise, the temperature of the two first cooling airflows A11 and A11′ generated by the two first fans 230a and 230b of the heat dissipation module 200b are between 35 degrees Celsius and 42 degrees Celsius, and the rotating element 140 is cooled to approximately 208 degrees Celsius through the heat dissipation module 200b. When the rotating element 140 rotates counterclockwise, the temperature of the two first cooling airflows A11 and A11′ generated by the two first fans 230a and 230b are between 35 degrees Celsius and 42 degrees Celsius, and the rotating element 140 is cooled to about 218 degrees Celsius through the heat dissipation module 200b. It can be seen that the auxiliary fan 220 may more effectively reduce the temperature of the first airflow A1, A1′ and the rotating element 140.

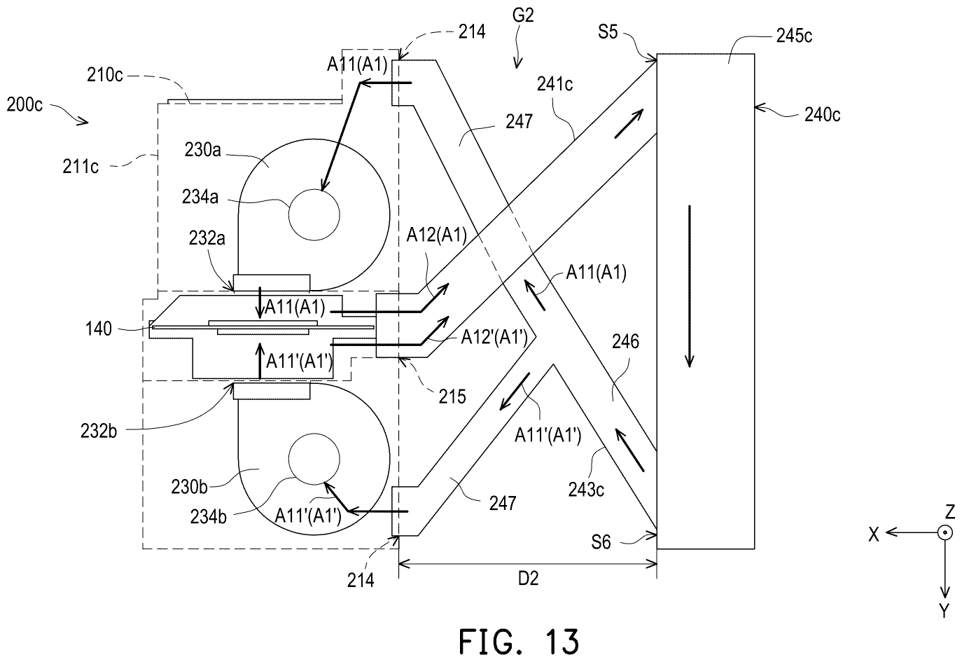

FIG. 13 is a schematic diagram of a heat dissipation module according to another embodiment of the disclosure. Referring to FIG. 10 and FIG. 13 at the same time, the heat dissipation module 200c of this embodiment is similar to the previous embodiment. The difference between the two is that the number of the outlet ducts 243c of the heat dissipation component 240c of this embodiment is one, and the number of first openings 214 of the housing 210c (the first housing 211c) is two. The outlet duct 243c and the inlet duct 241c are located at two opposite ends S5 and S6 of the heat dissipation component 240c. The inlet duct 241c is communicated to the second opening 215, and the outlet duct 243c is communicated to the two first openings 214.

Specifically, the outlet duct 243c of this embodiment includes a main duct 246 and two branch ducts 247. One end of the main duct 246 is connected to the two branch ducts 247, and the other end of the main duct 246 is connected to the main body 245c of the heat dissipation component 240c. The outlet duct 243c has, for example, a Y shaped. The two branch ducts 247 are connected to the two first openings 214 respectively. The distance D2 between the body 245c of the heat dissipation component 240c and the housing 210c is greater than the distance D1 between the heat dissipation component 240b and the housing 210b, so as to increase the size of the air inlet (the gap G2) of the auxiliary airflow A3 to increase the flow rate of the auxiliary airflow A3, thereby improving the heat dissipation efficiency of the heat dissipation module 200c. The heat dissipation module 200c of this embodiment has similar effects to the previous embodiment, and is not repeated herein.

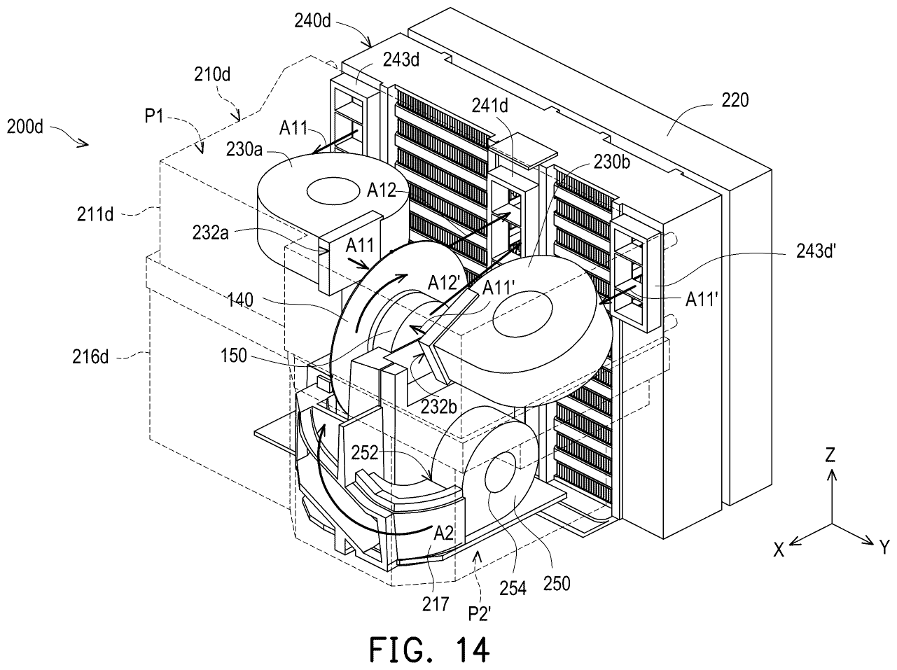

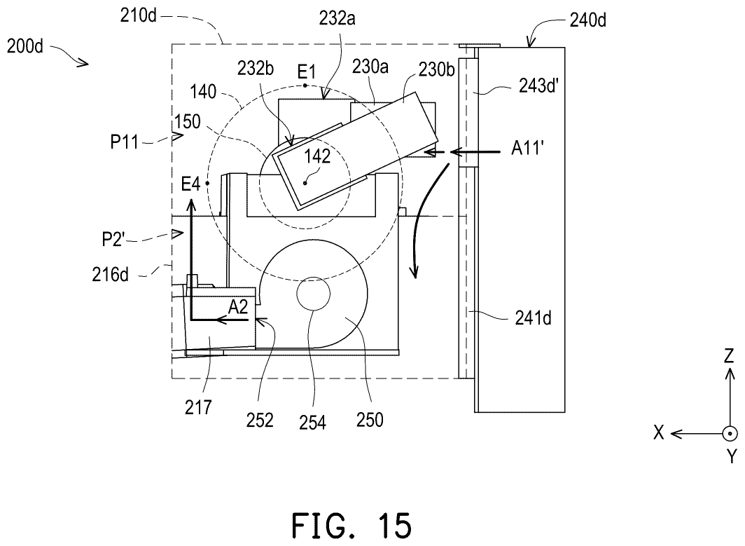

FIG. 14 is a schematic diagram of a heat dissipation module according to another embodiment of the disclosure. FIG. 15 is a side schematic view of the heat dissipation module of FIG. 14. Referring to FIG. 10 and FIG. 14 at the same time, the heat dissipation module 200d of this embodiment is similar to the previous embodiment. The difference between the two is that the heat dissipation module 240d of this embodiment further includes a second fan 250. The second fan 250 is disposed in the second space P2′ of the housing 210d (the second housing 216d). The two first fan outlets 232a and 232b of the two first fans 230a and 230b are at least partially offset along the Y-axis.

As shown in FIG. 14 and FIG. 15, the first fan outlet 232a of the first fan 230a corresponds to the edge position of the rotating element 140, such as the edge position E1 shown in FIG. 15. The first fan outlet 232b of the first fan 230b corresponds to the center 142 of the rotating element 140. Specifically, the first fan outlet 232b corresponds to a motor 150 of the projection device 100. The motor 150 is disposed on the housing 210d and connected to the center 142 of the rotating element 140. The motor 150 is configured to drive the rotating element 140 to rotate. The first fan 230b is configured to dissipate heat from the motor 150.

The second fan 250 includes a second fan inlet 254 and a second fan outlet 252. The second fan 250 is configured to generate a second airflow A2. The housing 210d includes an air guide channel 217 configured to guide the second airflow A2 flowing out from the second fan outlet 252. The air guide channel 217 is disposed in the second housing 216d (second space P2′) corresponding to the second fan 250. The second fan outlet 252 is connected to the air guide channel 217. The second airflow A2 generated by the second fan 250 flows out from the second fan outlet 252 and is guided to the edge position of the rotating element 140, such as the edge position E4 shown in FIG. 15, through the air guide channel 217 to perform heat exchange with the rotating element 140.

As shown in FIG. 14 and FIG. 15, the second airflow A2 with smaller thermal energy performs heat exchange with the rotating element 140. Due to the configuration of the housing 210d and the rotation of the rotating element 140, part of the second airflow A2 is guided to inlet duct 241d of the heat dissipation component 240d and flows into the heat dissipation component 240d for heat dissipation. The second airflow A2 flowing into the heat dissipation component 240d is regarded as the part of the first hot airflows A12, A12′. The first hot airflows A12 and A12′ exchange heat with the heat dissipation component 240d to form the first cooling airflows A11 and A11′. The first cooling airflows A11 and A11′ leave the heat dissipation component 240d through the outlet ducts 243d and 243d′.

Referring to FIG. 14 and FIG. 15 continuously, the first subspace P11 of this embodiment is communicated to the second space P2′. When the first cooling airflow A11′ flows from the outlet duct 243d′ into the first space P1 (the first subspace P11), part of the first cooling airflow A11′ enters the first fan 230b, and part of the first cooling airflow A11′ flows into the second space P2′ and enters the second fan 250 from the second fan inlet 254. At this point, the second airflow A2 completes one cooling cycle. The heat dissipation module 200d of this embodiment has similar effects to the previous embodiment, and is not repeated herein.

To sum up, the heat dissipation module and the projection device of the embodiment of the disclosure have at least one of the advantages: the heat dissipation module dissipates heat from the rotating element through the heat dissipation component and the first fan. The first fan generates a first airflow to cool the rotating element. The inlet duct of the heat dissipation component corresponds to the rotation tangential direction of the rotating element, thereby the rotating element guides the first airflow into the heat dissipation component to cool the first airflow to improve the heat dissipation efficiency of the heat dissipation module and the projection device.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A heat dissipation module, configured to dissipate heat from a rotating element rotated with a first axis as a rotation axis, the heat dissipation module comprises at least one first fan and a heat dissipation component, wherein:
the at least one first fan is disposed to one side of the rotating element and comprises a first fan outlet, the first fan outlet faces the rotating element, a first airflow generated by the at least one first fan flows from the first fan outlet to the rotating element; and
the heat dissipation component comprises an inlet duct, a plurality of inner ducts and at least one outlet duct, the plurality of inner ducts are communicated to the inlet duct and the at least one outlet duct, the at least one outlet duct corresponds to the at least one first fan,
wherein the inlet duct of the heat dissipation component is disposed corresponding to a rotation tangential direction of the rotating element, and the rotation tangential direction is perpendicular to the first axis.

2. The heat dissipation module according to claim 1, wherein each of the at least one first fan comprises a first fan inlet, at least part of the first airflow is guided from the inlet duct into the heat dissipation component via the rotating element, and leaves the heat dissipation component from the corresponding at least one outlet duct to form a first cooling airflow, at least part of the first cooling airflow enters the first fan inlet.

3. The heat dissipation module according to claim 1, wherein a length of the inlet duct along an extension axis is greater than or equal to a radius of the rotating element, the extension axis is perpendicular to the first axis and a normal direction of an air inlet surface of the inlet duct.

4. The heat dissipation module according to claim 1, wherein an orthographic projection of a center of the rotating element to the heat dissipation component is located in the inlet duct.

5. The heat dissipation module according to claim 1, wherein the number of the at least one first fan is two, the number of the at least one outlet duct is two, the two first fans are disposed on two opposite sides of the rotating element, the inlet duct is located between the two outlet ducts, and the two first fans respectively correspond to the two outlet ducts.

6. The heat dissipation module according to claim 1, further comprising a housing, the housing comprises a first space, the rotating element is located in the housing, the at least one first fan is disposed in the first space of the housing, and the heat dissipation component is disposed outside the housing and communicated to the housing.

7. The heat dissipation module according to claim 6, wherein further comprising a second fan, the housing further comprises a second space, the second fan is disposed in the second space of the housing, the second fan comprises a second fan outlet, and a second airflow generated by the second fan flows from the second fan outlet to the rotating element.

8. The heat dissipation module according to claim 6, wherein the heat dissipation component further comprises a plurality of fins, and the plurality of fins are connected between the adjacent inner ducts, an auxiliary airflow flows through gaps between the adjacent plurality of fins, and the heat dissipation module further comprises an auxiliary fan, the auxiliary fan and the housing are respectively disposed on two opposite edges of the heat dissipation component, and the auxiliary fan is located on the on a moving path of the auxiliary airflow.

9. The heat dissipation module according to claim 1, further comprising a housing, the housing comprises a first housing and a second housing, the first housing comprises a first space, the second housing comprises a second space, the first space comprises at least one first subspace and a second subspace, the first housing comprises at least one partition plate, the at least one partition plate comprises a fan opening and is located at a boundary between the at least one first subspace and the second subspace, the at least one first fan is located in the at least one first subspace, part of the rotating element is located in the second subspace, and the fan opening corresponds to the first fan outlet.

10. The heat dissipation module according to claim 9, wherein the first housing comprises at least one first opening and a second opening, the at least one first opening corresponds to the at least one first opening, the second opening corresponds to the second subspace, the at least one first opening is connected to the at least one outlet duct, and the second opening is connected to the inlet duct.

11. The heat dissipation module according to claim 9, wherein the first housing comprises two first openings and a second opening, the number of the at least one outlet duct is one, and the second opening is located between the two first openings, the outlet duct and the inlet duct are located at two opposite ends of the heat dissipation component, the inlet duct is communicated to the second opening, and the outlet duct is communicated to the two first openings.

12. A projection device, comprising:
an illumination system, configured to provide an illumination beam, the illumination system comprises a light source module, a heat dissipation module and a rotating element, the light source module is configured to provide a light beam, the rotating element is disposed on a transmission path of at least part of the light beam, the rotating element rotates around a first axis as a rotation axis, and the illumination beam comprises at least part of the light beam, the heat dissipation module is configured to dissipate heat to the rotating element, the heat dissipation module comprises at least one first fan and a heat dissipation component, wherein:
the at least one first fan is disposed to one side of the rotating element and comprises a first fan outlet, the first fan outlet faces the rotating element, a first airflow generated by the at least one first fan flows from the first fan outlet to the rotating element; and
the heat dissipation component comprises an inlet duct, a plurality of inner ducts and at least one outlet duct, the plurality of inner ducts are communicated to the inlet duct and the at least one outlet duct, the at least one outlet duct corresponds to the at least one first fan, wherein the inlet duct of the heat dissipation component is disposed corresponding to a rotation tangential direction of the rotating element, and the rotation tangential direction is perpendicular to the first axis;
a light valve, disposed on a transmission path of the illumination beam to convert the illumination beam into an image beam; and
a lens module, disposed on a transmission path of the image beam to project the image beam.

13. The projection device according to claim 12, wherein each of the at least one first fan comprises a first fan inlet, at least part of the first airflow is guided from the inlet duct into the heat dissipation component via the rotating element, and leaves the heat dissipation component from the corresponding at least one outlet duct to form a first cooling airflow, at least part of the first cooling airflow enters the first fan inlet.

14. The projection device according to claim 12, wherein a length of the inlet duct along an extension axis is greater than or equal to a radius of the rotating element, the extension axis is perpendicular to the first axis and a normal direction of an air inlet surface of the inlet duct.

15. The projection device according to claim 12, wherein an orthographic projection of a center of the rotating element to the heat dissipation component is located in the inlet duct.

16. The projection device according to claim 12, wherein the number of the at least one first fan is two, the number of the at least one outlet duct is two, the two first fans are disposed on two opposite sides of the rotating element, the inlet duct is located between the two outlet ducts, and the two first fans respectively correspond to the two outlet ducts.

17. The projection device according to claim 12, wherein the heat dissipation module further comprises a housing, the housing comprises a first space, the rotating element is located in the housing, the at least one first fan is disposed in the first space of the housing, and the heat dissipation component is disposed outside the housing and communicated to the housing.

18. The projection device according to claim 17, wherein the heat dissipation module further comprises a second fan, the housing further comprises a second space, the second fan is disposed in the second space of the housing, the second fan comprises a second fan outlet, and a second airflow generated by the second fan flows from the second fan outlet to the rotating element.

19. The projection device according to claim 17, wherein the heat dissipation component further comprises a plurality of fins, and the plurality of fins are connected between the adjacent inner ducts, an auxiliary airflow flows through gaps between the adjacent plurality of fins, and the heat dissipation module further comprises an auxiliary fan, the auxiliary fan and the housing are respectively disposed on two opposite edges of the heat dissipation component, and the auxiliary fan is located on the on a moving path of the auxiliary airflow.

20. The projection device according to claim 12, wherein the heat dissipation module further comprises a housing, the housing comprises a first housing and a second housing, the first housing comprises a first space, the second housing comprises a second space, the first space comprises at least one first subspace and a second subspace, the first housing comprises at least one partition plate, the at least one partition plate comprises a fan opening and is located at a boundary between the at least one first subspace and the second subspace, the at least one first fan is located in the at least one first subspace, part of the rotating element is located in the second subspace, and the fan opening corresponds to the first fan outlet.

21. The projection device according to claim 20, wherein the first housing comprises at least one first opening and a second opening, the at least one first opening corresponds to the at least one first opening, the second opening corresponds to the second subspace, the at least one first opening is connected to the at least one outlet duct, and the second opening is connected to the inlet duct.

22. The projection device according to claim 20, wherein the first housing comprises two first openings and a second opening, the number of the at least one outlet duct is one, and the second opening is located between the two first openings, the outlet duct and the inlet duct are located at two opposite ends of the heat dissipation component, the inlet duct is communicated to the second opening, and the outlet duct is communicated to the two first openings.
